(19) United States
(12) Patent Application Publication
(10) Pub. No.: US 2023/0369540 A1
(43) Pub. Date: Nov. 16, 2023

(54) SEMICONDUCTOR STACK

(71) Applicant: EPISTAR CORPORATION, Hsinchu (TW)

(72) Inventor: Feng-Wen HUANG, Hsinchu (TW)

(21) Appl. No.: 18/196,015

(22) Filed: May 11, 2023

(30) Foreign Application Priority Data
May 11, 2022 (TW) 111117590

(51) Int. Cl. H01L 33/24

(52) U.S. Cl. CPC H01L 33/24; H01L 33/06

(57) ABSTRACT

A semiconductor stack includes a first-type semiconductor layer, a second-type semiconductor layer, an active region located between the first-type semiconductor layer and the second-type semiconductor layer, one or multiple recesses, and a recess-induced layer located between the first-type semiconductor layer and the active region. The active region has a first thickness and includes an upper surface and a lower surface closer to the first-type semiconductor layer than the upper surface. Each recess includes a bottom disposed in the active region. A first distance is from the bottom of the recess to the lower surface. The first distance is 0.5-0.9 times the first thickness.

### CROSS-REFERENCE TO RELATED APPLICATIONS

This disclosure claims the right of priority of TW Application No. 111117590 filed on May 11, 2022, and the content of which is hereby incorporated by reference in its entirety.

### BACKGROUND

### Technical Field

The present disclosure relates to a semiconductor stack, in specific, to a semiconductor stack including recesses.

### Description of the Related Art

The light-emitting diode (LED) is a sort of solid-state semiconductor element, which has the advantages of low power consumption, low heat generation, long lifetime, shockproof, small size, high response speed, and good optical-electrical characteristics like stable emission wavelength. Therefore, light-emitting diodes have been widely applied to household appliances, equipment indicator lights, optoelectronic products, and so forth.

### SUMMARY

The present application discloses a semiconductor stack including a first-type semiconductor layer, a second-type semiconductor layer, an active region located between the first-type semiconductor layer and the second-type semiconductor layer, one or multiple recesses, and a recess-induced layer located between the first-type semiconductor layer and the active region. The active region has a first thickness and includes an upper surface and a lower surface closer to the first-type semiconductor layer than the upper surface. Each recess includes a bottom disposed in the active region. A first distance is from the bottom of the recess to the lower surface. The first distance is 0.5-0.9 times the first thickness.

### BRIEF DESCRIPTION OF THE DRAWINGS

FIG. 1 shows a schematic cross-sectional view of a semiconductor stack 1E in accordance with an embodiment of the present application.

FIG. 2 shows an enlargement of a schematic cross-section of enlargement of the active region 150 of semiconductor stack 1E in an embodiment of the present application.

FIG. 3 shows a schematic cross-sectional view of a light-emitting element 1C in accordance with an embodiment of the present application.

FIG. 4 shows a schematic cross-sectional view of a light-emitting element 2C in accordance with an embodiment of the present application.

FIG. 5 shows a schematic cross-sectional view of a light-emitting package 1P in accordance with an embodiment of the present application.

FIG. 6 shows a schematic cross-sectional view of a light-emitting package 2P in accordance with an embodiment of the present application.

FIG. 7 shows a schematic cross-sectional view of a light-emitting device 1A in accordance with an embodiment of the present application.

### DETAILED DESCRIPTION OF THE EMBODIMENTS

The following embodiments will be described with reference to the accompanying drawings. In the description or drawings, similar or identical parts are labeled with the same reference numeral. In the drawings, the shape or thickness of the components may be enlarged or reduced. It should be noted that elements known by those skilled in the art may be omitted in the drawings or the description. In the drawings, similar components are indicated by similar reference numerals. The following descriptions and accompanying drawings are simply provided for illustration instead of limitation. It may be expected that components and features in one embodiment may be beneficially incorporated in another embodiment without further recitation. In addition, other layers/structures or steps may be incorporated in the following embodiments. For example, a description of “forming a second layer/structure on a first layer/structure” may include an embodiment which the first layer/structure directly contacts the second layer/structure, or an embodiment which the first layer/structure indirectly contacts the second layer/structure, namely other layers/structures between the first layer/structure and the second layer/structure. In addition, the spatially relative relationship between the first layer/structure and the second layer/structure may be varied depending on the operation or usage of the device, the first layer/structure is not limited to a single layer or a single structure, and the first layer may include sub-layers, and the first structure may include multiple sub-structures.

In addition, spatially relative terms, such as “beneath,” “below,” “lower,” “above,” “upper”, “top”, “bottom” and the like, may be used herein for ease of description to describe one element or feature’s relationship to another element(s) or feature(s) as illustrated in the drawings. The spatially relative terms are also used to describe the possible orientations of a semiconductor stack and light-emitting element in use or operation in addition to the orientation depicted in the drawings. The apparatus may be otherwise oriented (rotated 90 degrees or at other orientations) and the spatially relative descriptors used herein may likewise be interpreted accordingly.

In the present application, if not specifically mention, the general expression of AlGaN means AlₐGa₍₁₋ₐ₎N, wherein 0≤a≤1; the general expression of InGaN means In_{b}Ga_{(1-b)}N, wherein 0≤b≤1; the general expression of AlInGaN means Al_{c}In_{d}Ga_{(1-c-d)}N, wherein 0≤c≤1, 0≤d≤1. The content of the element can be adjusted for different purposes, such as, but not limited to, adjusting the energy gap or the peak wavelength of the light emitted from the semiconductor stack.

The compositions and dopants of each layer in the semiconductor stack of the present application can be determined by any suitable means, such as secondary ion mass spectrometer (SIMS).

The thickness of each layer in the semiconductor stack disclosed in the present application may be analyzed by suitable means, such as transmission electron microscopy (TEM) or scanning electron microscope (SEM), thereby corresponding to, for example, the depth position of each layer on the SIMS map.

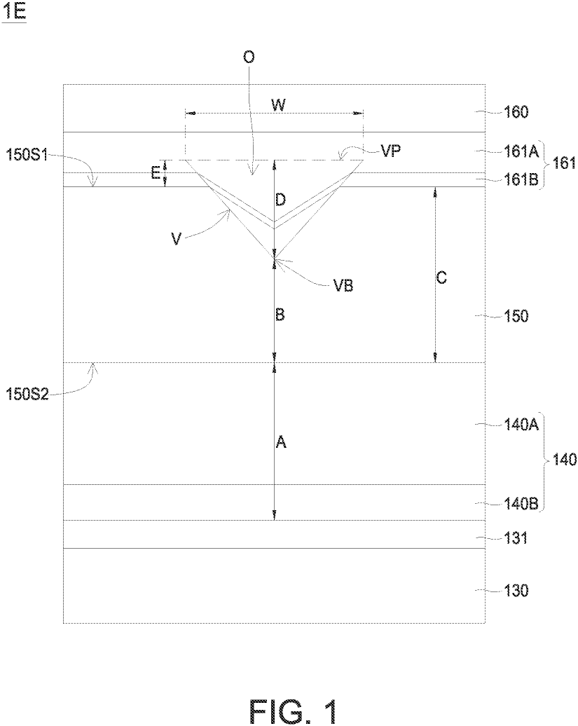

FIG. 1 shows a cross-sectional view of a semiconductor stack 1E in accordance with an embodiment of the present application. The semiconductor stack 1E includes a first-type semiconductor layer 130, a second-type semiconductor layer 160, an active region 150 located between the first-type semiconductor layer 130 and the second-type semiconductor layer 160, and a recess-filled layer 161 located between the second-type semiconductor layer 160 and the active region 150. In one embodiment, a low doped layer 131 may be further located between the first-type semiconductor layer 130 and the recess-induced layer 140. In one embodiment, the first-type semiconductor layer 130 includes a first conductivity-type dopant, and the second-type semiconductor layer 160 includes a second conductivity-type dopant. By doping the first and second conductivity-type dopants into the first-type semiconductor layer 130 and the second-type semiconductor layer 160 respectively, the first-type semiconductor layer 130 and the second-type semiconductor layer 160 may have different conductivity-types, electric properties, polarities or are respectively used to provide electrons or holes. In one embodiment, the low doped layer 131 may include the first conductivity-type dopant or not. In one embodiment, the recess-induced layer 140 may include the first conductivity-type dopant. In one embodiment, the first conductivity-type dopant and the second conductivity-type dopant may be n-type dopant or p-type dopant respectively. In one embodiment, the n-type dopant includes a group IV element, such as silicon, and the p-type dopant includes a group II element, such as magnesium. The first-type semiconductor layer 130 and the recess-induced layer 140 may be n-type semiconductor layers, and the low doped layer 131 may include the n-type dopant or not. The low doped layer 131 may be an n-type semiconductor layer or an i-type semiconductor layer, and the second-type semiconductor layer 160 and the recess-filled layer 161 may be p-type semiconductor layer. The active region 150 has an upper surface 150S1 and a lower surface 150S2 closer to the first-type semiconductor layer 130 than the upper surface 150S1. The recess-induced layer 140 includes a recess-induced first sublayer 140A and a recess-induced second sublayer 140B. The recess-induced first sublayer 140A is located between the recess-induced second sublayer 140B and the active region 150. The recess-induced first sublayer 140A may directly contact the lower surface 150S2. The recess-filled layer 161 includes a recess-filled first sublayer 161A and a recess-filled second sublayer 161B. The recess-filled second sublayer 161B is located between the recess-filled first sublayer 161A and the active region 150.

In one embodiment, the semiconductor stack 1E may be formed on a growth substrate (not shown) by epitaxial growth. The growth substrate may include a sapphire (Al₂O₃) substrate, a gallium nitride (GaN) substrate, a silicon carbide (SiC) substrate or an aluminum nitride (AlN) substrate. In one embodiment, the growth substrate may be a patterned substrate, that is, a surface of the growth substrate which the semiconductor stack 1E is formed on may have a patterned structure.

In any embodiment of the present application, the way for processing epitaxial growth may include metal organic chemical vapor deposition (MOCVD), hydride vapor deposition (HVPE), molecular beam epitaxy (MBE), physical vapor deposition (PVD) or liquid-phase epitaxy (LPE) method, but is not limited thereto. MOCVD epitaxial growth method will be used for representative description in the following embodiments.

The semiconductor stack 1E includes a semiconductor light-emitting stack constituting a light-emitting element such as a light-emitting diode or a laser. By changing the physical and chemical composition of one or more layers, such as the active region 150, of the semiconductor stack 1E, the wavelength of the emitted light thereof can be adjusted. The first-type semiconductor layer 130, the low doped layer 131, the recess-induced layer 140, the active region 150, the recess-filled layer 161 and the second-type semiconductor layer 160 may include the same series of III-V semiconductor materials, such as InGaN series materials, AlGaN series materials or AlInGaN series materials. When the material of the active region 150 includes InGaN series materials, a blue light with a wavelength between 400 nm and 490 nm, a cyan light (Cyan) with a wavelength between 490 nm and 530 nm, or a green light with a wavelength between 530 nm and between 570 nm can be emitted from the active region 150. When the material of the active region 150 includes AlGaN series or AlInGaN series materials, an ultraviolet light with a wavelength between 250 nm and 400 nm can be emitted from the active region 150. In one embodiment, the active region 150 may include a single heterostructure, a double heterostructure, or a multiple quantum well. In one embodiment, the materials of the active region 150 may be i-type, p-type or n-type semiconductors.

In one embodiment, before forming the semiconductor stack 1E, a buffer structure (not shown) can be formed on the growth substrate. The buffer structure can reduce the dislocation caused by the lattice mismatch between the growth substrate and the semiconductor stack 1E to improve the epitaxy quality. The buffer structure may contain a single layer or multiple layers. In one embodiment, the buffer structure includes AlᵢGa₍₁₋ᵢ₎N, wherein 0≤i≤1. In one embodiment, the material of the buffer structure includes GaN. In another embodiment, the material of the buffer structure includes AlN. The way for forming the buffer structure can be MOCVD, MBE, HVPE or PVD. The PVD includes sputtering or electron beam evaporation. When the buffer structure includes multiple sublayers (not shown), the sublayers include the same material or different materials. In one embodiment, the buffer structure includes two sublayers, wherein the first sublayer is grown by sputtering, and the second sublayer is grown by MOCVD. In one embodiment, the buffer structure includes a third sublayer. The third sublayer is grown by MOCVD, and a growth temperature of the second sublayer may be higher or lower than a growth temperature of the third sublayer. In one embodiment, the first, second and third sub-layers include the same material, such as AlN, or a combination of different materials, such as AlN, GaN and AlGaN. In another embodiments, PVD-AlN may be the buffer layer, and a target used to form PVD-AlN is composed of aluminum nitride, or using an aluminum-composed target in a nitrogen-source environment to reactively form aluminum nitride. In one embodiment, the buffer structure may be doped, i.e., not intentionally doped. In another embodiment, the buffer structure may include a dopant such as silicon, carbon, hydrogen, oxygen or a combination thereof, and the concentration of this dopant in the buffer structure is not less than 1×10¹⁷/cm³.

Referring to FIG. 1, the semiconductor stack 1E may include one or multiple recesses V. In one embodiment, the recesses V may be V-shaped recesses. FIG. 1 shows one recess V for representatively describing. In one embodiment, the recess V has a bottom VB and an opening O, and the bottom VB of the recess V is located in the active region 150. The recess V may be a hexagonal conical recess, and the bottom VB thereof has a pointed bottom in a cross-sectional view. When the active region 150 is epitaxially grown, the opening size of the recess V gradually increases with the growth direction. In one embodiment, the recess V has an opening O with a maximum opening width W in the recess-filled layer 161. In one embodiment, the recess V can be filled up in the recess-filled layer 161, and then the following stack can be subsequently grown. The recess V has a filled surface VP located in the recess-filled layer 161. In one embodiment, the recess V can be filled up in the active region 150 and has the filled surface VP in the active region 150.

Due to intrinsic physical limitations, the main recombination region for recombining the electrons and the holes in the active region 150 is closer to the p-type semiconductor layer. For example, in the present embodiment, the recess-filled layer 161 is a p-type doped layer, so in the active region 150 the main recombination region may be in a region close to the recess-filled layer 161. In one embodiment, the recess V has an inclined plane, the thickness of the barrier layers and the wells layer on the inclined plane is thinner than that on the planes outside of the recess V. For example, when the growth substrate is a sapphire substrate, the surface for epitaxial growth of the growth substrate is a polar plane (C-plane), and the inclined plane of the recess V is a semi-polar surface, thereby making the holes easier to tunnel the barrier layers and the well layers, so the injection of holes can be increased to improve the light-emitting efficiency. In addition, the recess V may increase current spreading path to improve anti-ESD effect of the semiconductor stack 1E. In addition, the appropriate number and size of recess V can reduce the probability of carriers falling into dislocation defects and reduce the conduction and activity of dislocation defects, thereby reducing the probability of non-radiative recombination. Therefore, the forward and reverse leakage of the light-emitting element may be effectively reduced. Further, the deterioration of the light-emitting efficiency of the light-emitting element driven at high temperature or high current can be prevented, thereby improving the reliability of the light-emitting element. However, too much recesses V or too large area of an inclined plane of a recess V may reduce the light-emitting area of the active region 150. Therefore, by adjusting the position of the recess V, and then maintaining the number and size of the recess V within a certain range, the light-emitting efficiency and reliability of the light-emitting element can be improved. In one embodiment, the active region 150 has a first thickness C, a first distance B can be defined from the bottom VB of the recess V to the lower surface 150S2 of the active region 150, and the first distance B is 0.5 to 0.9 times the first thickness C. In one embodiment, the recess-induced layer 140 has a second thickness A, and the first distance B is 0.3 to 2.7 times the second thickness A. In one embodiment, the sum of the second thickness A and the first distance B is 0.4-1 times the sum of the second thickness A and the first thickness C. In one embodiment, the sum of the second thickness A and the first distance B is 0.6-1 times the sum of the second thickness A and the first thickness C. The first thickness C is 0.4-0.8 times the sum of the second thickness A and the first thickness C. In one embodiment, the recess V has a depth D, and a second distance E is from the filled surface VP to the upper surface 150S1 of the active region 150. The second distance E is 0.1-3 times the depth D. In one embodiment, the first thickness C is in a range of 250 to 340 nm, the first distance B is in a range of 90 to 270 nm, the second thickness A is in a range of 100 to 300 nm, the depth D is in a range of 50 to 250 nm, and the second distance E is in a range of 25 to 150 nm. In one embodiment, the maximum opening width W of the opening O of the recess V is 50-200 nm. The thickness of the recess-induced layer 140 has a proportional relationship with the first distance B, the depth D and the maximum opening width W within a certain range. Within such certain ranges, a thicker recess-induced layer 140 may result in a smaller first distance B, a greater depth D and a greater maximum opening width W to increase holes injection and current spreading path. The above-mentioned width, depth, thickness, distance range and proportional relationship have been described in detail above.

In one embodiment, the growth conditions of the first-type semiconductor layer 130 and the low doped layer 131 may be the same or different. The growth conditions may include temperature, pressure, organometallic reaction source ratio and flow, dopant concentration, or material composition caused by the above conditions. In one embodiment, when the first-type semiconductor layer 130 and the low doped layer 131 have the same growth conditions, the growth conditions between them, such as temperature, may have a difference of less than 10% to maintain the epitaxial quality of the underlying layer of the semiconductor stack 1E. In one embodiment, the composed materials of the first-type semiconductor layer 130 and the low doped layer 131 may be the same or different. In one embodiment, the dopant concentrations of first-type semiconductor layer 130 and a low doped layer 131 may be the same or different. The material of the firs-type semiconductor layer 130 includes AlaGa(1-a)N, wherein 0 < α ≦ 1. The material of the low doped layer 131 contains Al_{b}Ga_{(1-b)}N, wherein the difference between a and b is between 0 and 0.1 (two endpoints included). The concentration of the first conductivity-type dopant of the first-type semiconductor layer 130 is greater than that of the low doped layer 131. In one embodiment, the concentration of the first conductivity-type dopant of the first-type semiconductor layer 130 is greater than 1×10¹⁸/cm³, for example, greater than 1×10¹⁹/m³, or between 1×10¹⁹/m³ and 9×10¹⁹/cm³ (two endpoints included). In one embodiment, the concentration of the first conductivity-type dopant of the low doped layer 131 is greater than 1×10¹⁶/cm³. For example, greater than 1×10¹⁷/cm³, or between 1×10¹⁷/cm³ and 1×10¹⁹/cm³ (two endpoints included).

In one embodiment, the recess-induced layer 140 is located between the first-type semiconductor layer 130 or low doped layer 131 and the active region 150. The growth conditions of the first-type semiconductor layer 130 or the low doped layer 131 are different from that of the active region 150. The growth conditions may include temperature, pressure, the proportion and flow rate of the organometallic reaction source. Therefore, to reduce the impact on epitaxy quality caused by differences in growth conditions between the first-type semiconductor layer 130 and/or lowly doped layer 131 and the active region 150, the recess-induced layer 140 may serve as a conditional transition structure between the first-type semiconductor layer 130 and the active layer 150 or between the low doped layer 131 and the active region 150 to maintain epitaxial crystal quality. In one embodiment, for example, by adjusting the growth conditions, and/or structures such as material composition, dopant, thickness of the recess-induced layer 140 to be different from that of the first-type semiconductor layer 130 or lowly doped layer 131, the forming position, the appropriate size and/or quantity of the recess V can be adjusted to increase holes injection and current spreading path, thereby improving the light-emitting efficiency and reliability of the light-emitting element.

In one embodiment, the growth condition of the recess-induced layer 140 may be different from that of the first-type semiconductor layer 130 and/or low doped layer 131. The growth condition may include temperature, pressure, flow rate and ratio of organometallic reaction source. In one embodiment, the growth temperature of the recess-induced layer 140 may be less than that of the first-type semiconductor layer 130 and/or the low doped layer 131. In one embodiment, the growth temperatures are different between the recess-induced layer 140 and the first-type semiconductor layer 130 and/or between the recess-induced layer 140 and the low doped layer 131. A ratio of the growth temperature difference to the growth temperature of the first-type semiconductor layer 130 and/or the low doped layer 131 is in a range of 10% to 30% (two endpoints included). In one embodiment, the ratio is greater than 15%. In one embodiment, the recess-induced layer 140 includes a recess-induced first sublayer 140A and a recess-induced second sublayer 140B. The growth temperature of the recess-induced second sublayer 140B and/or the recess-induced first sublayer 140A may be less than that of the first-type semiconductor layer 130 and/or the low doped layer 131. In one embodiment, the growth temperatures are different between the recess-induced second sublayer 140B and/or recess-induced first sublayer 140A and the first-type semiconductor layer 130 and/or low doped layer 131. A ratio of the growth temperature difference to the growth temperature of the first-type semiconductor layer 130 and/or low doped layer 131 is in a range of 10% to 30% (two endpoints included). In one embodiment, the ratio is greater than 15%. In one embodiment, the epitaxial structure of the recess-induced layer 140 is stacked by a plurality of island-like structures. The epitaxial structure of the first-type semiconductor layer 130 and/or the low doped layer 131 may be a continuous layered structure. In one embodiment, the epitaxial structure of recess-induced first sublayer 140A and/or the recess-induced second sublayer 140B in the recess-induced layer 140 is stacked by a plurality of island-like structures. The epitaxial structure of the first-type semiconductor layer 130 and/or the low doped layer 131 may be a continuous layered structure. In one embodiment, the epitaxial surface reflectivity of the recess-induced layer 140 is less than that of the first-type semiconductor layer 130 and/or the low doped layer 131. In one embodiment, the epitaxial surface reflectivity of the recess-induced first sublayer 140A and/or the recess-induced second sublayer 140B in the recess-induced layer 140 is less than that of the first-type semiconductor layer 130 and/or the low doped layer 131. In above embodiment, by adjusting the growth conditions and the form of epitaxial layer of the recess-induced layer 140, the difference in growth conditions between the first-type semiconductor layer 130 and the active region 150 and/or between the low doped layer 131 and the active region 150 can be reduced to maintain epitaxial crystal quality. In addition, since the growth conditions and the form of epitaxial layer of the recess-induced layer 140 are adjusted, and the active region 150 is sequentially grown thereon, enough stress can be generated and accumulated in the active region 150 to form one or multiple recesses V therein. However, the present application is not limited to above embodiments, the recess-induced layer 140 may be composed of the recess-induced first sublayer 140A without the recess-induced second sublayer 140B. In another embodiment, the recess-induced layer 140 may be composed of the recess-induced second sublayer 140B without the recess-induced first sublayer 140A. In another embodiment, the recess-induced layer 140 includes the recess-induced first sublayer 140A, the recess-induced second sublayer 140B, and other multiple sublayers (not shown). Under a condition of maintaining the epitaxial quality, the growth conditions difference between the first-type semiconductor layer 130 and the low doped layer 131, between the low doped layer 131 and the recess-induced second sublayer 140B, between the recess-induced second sublayer 140B and the recess-induced first sublayer 140A, and between other multiple sublayers may be increased, thereby increasing the stress in the epitaxial stack so as to form the recess V in the active region 150.

In one embodiment, each of the active region 150, the recess-induced layer 140 and the first-type semiconductor layer 130 includes a group IV dopant, such as carbon. Group IV dopant sources can be included in the epitaxial raw materials or additionally added during an epitaxial growth process. In one embodiment, the concentration of group IV dopant of the recess-induced layer 140 is greater than or equal to that of the first-type semiconductor layer 130. In one embodiment, the concentration of group IV dopant of the recess-induced layer 140 is less than or equal to that of the active region 150. In one embodiment, the concentration of group IV dopant in the first-type semiconductor layer 130 is greater than 2×10¹⁶/cm³, for example, greater than 3×10¹⁶/cm³, or between 3×10¹⁶/cm³ and 5×10¹⁶/cm³ (two endpoints included). In one embodiment, the concentration of group IV dopant of the recess-induced layer 140 is greater than 3×10¹⁶/cm³, for example, greater than 4×10¹⁶/cm³, or between 4×10¹⁶/cm³ and 9×10¹⁶/cm³ (two endpoints included). In one embodiment, the concentration of group IV dopant of the active region 150 is greater than 8×10¹⁶/cm³, for example, greater than 9×10¹⁶/cm³, or between 9×10¹⁶/cm³ and 2×10¹⁷/cm³ (two endpoints included). In one embodiment, the concentration of group IV dopant of the recess-induced layer 140A of the recess-induced layer 140 is greater than 3×10¹⁶/cm³, for example, greater than 4×10¹⁶/cm³, or between 4×10¹⁶/cm³ and 7×10¹⁶/cm³ (two endpoints included). In one embodiment, the concentration of group IV dopant of the recess-induced layer 140B of the recess-induced second sublayer 140 is greater than 4×10¹⁶/cm³, for example, greater than 5×10¹⁶/cm³, or between 5×10¹⁶/cm³ and 9×10¹⁶/cm³ (two endpoints included). In one embodiment, the concentration of group IV dopant of the recess-induced first sublayer 140A of the recess-induced layer 140 may be the same or different from that of the recess-induced second sublayer 140B of the recess-induced layer 140. In one embodiment, the concentration of group IV dopant of the recess-induced first sublayer 140A of the recess-induced layer 140 is less than that of the recess-induced layer 140B of the recess-induced layer 140. In one embodiment, the concentration of group IV dopant of the recess-induced first sublayer 140A of the recess-induced layer 140 is greater than that of recess-induced second sublayer 140B of the recess-induced layer 140. In one embodiment, the recess-induced layer 140 has a peak concentration of group IV dopant. In one embodiment, the peak concentration of group IV dopant may be in the recess-induced first sublayer 140A or the recess-induced second sublayer 140B of the recess-induced layer 140. In one embodiment, the concentration of group IV dopant of the recess-induced layer 140 may be higher resulted from the growth temperature of the recess-induced layer 140, thereby effectively reducing the leakage and reverse voltage of the light-emitting element.

In one embodiment, the material of the recess-induced layer 140 includes Al_{c}Ga_{(1-c)}N, wherein 0 < c ≦ 1, and the material of the low doped layer 131 includes Al_{b}Ga_{(1-b)}N, wherein 0 < b ≦ 1, and 0 < c ≦ 1. In one embodiment, the material of the recess-induced second sublayer 140A of the recess-induced layer 140 include AlₓGa₍₁₋ₓ₎N, wherein 0 < x ≦ 1. In one embodiment, b < x ≦ 1. In one embodiment following the above embodiment, the material of the recess-induced second sublayer 140B of the recess-induced layer 140 include Aly_{G}a_{(1-y)}N, and b<x≦y≦1. In one embodiment, the concentration of the first conductivity-type dopant of the recess-induced layer 140 is less than that of the first-type semiconductor layer 130. In one embodiment, the concentration of the first conductivity-type dopant of the recess-induced layer 140 is greater than or equal to that of the low doped layer 131. In one embodiment, the concentration of the first conductivity-type dopant of the recess-induced layer 140 is greater than 1×10¹⁷/cm³, for example, greater than 1×10¹⁸/cm³, or between 1×10¹⁸/cm³ and 1×10¹⁹/m³ (two endpoints included). In one embodiment, the concentrations of the first conductivity-type dopant of the recess-induced first sublayer 140A and the recess-induced second sublayer 140B are greater than 1 × 10¹⁷/cm³, for example, greater than 1 × 10¹⁸/cm³, or between 1×10¹⁸/cm³ and 1×10¹⁹/cm³ (two endpoints included). In one embodiment, the concentration of the first conductivity-type dopant of the recess-induced second sublayer 140B may be the same or different from that of the recess-induced first sublayer 140A. In one embodiment, the concentration of the first conductivity-type dopant of the recess-induced second sublayer 140B is greater than that of the recess-induced first sublayer 140A. In one embodiment, the concentration of the first conductivity-type dopant of the recess-induced second sublayer 140B is less than that of the recess-induced first sublayer 140A. In one embodiment, the thickness of the recess-induced first sublayer 140A is the same or different from that of the recess-induced second sublayer 140B. In one embodiment, the thickness of the recess-induced first sublayer 140A is less than that of the recess-induced second sublayer 140B. In one embodiment, the thickness of the recess-induced first sublayer 140A is greater than that of the recess-induced second sublayer 140B. In one embodiment, the thickness of the recess-induced first sublayer 140A or the recess-induced second sublayer 140B is between 100 nm and 300 nm (two endpoints included). In one embodiment, the thickness of the recess-induced first sublayer 140A or the recess-induced second sublayer 140B is between 10 nm and 50 nm (two endpoints included). In above embodiments, by adjusting the material composition, dopant concentration and thickness of the recess-induced layer 140, sufficient stress can be generated and accumulated in the subsequent active region 150, and then one or multiple recesses V are formed in the active region 150. In one embodiment, by making the aluminum composition and/or the dopant concentration of the recess-induced second sublayer 140B greater or less than those of the recess-induced first sublayer 140A, a stress may occur in the recess-induced second sublayer 140B and the recess-induced first sublayer 140A caused by the difference of aluminum composition and/or dopant concentration. In another embodiment, the stress in the semiconductor stack can be accumulated by forming the recess-induced layer 140, such as forming the recess-induced second sublayer 140B and the recess-induced first sublayer 140A, or the stress in the semiconductor stack can be accumulated by forming more recess-induced sublayers between the low doped layer 131 and the active region 150. In one embodiment, the thickness of the recess-induced first sublayer 140A is greater than that of the recess-induced second sublayer 140B. One or more recesses V are formed in the active region 150 by accumulating stress in the recess-induced first sublayer 140A. The thickness of the recess-induced second sublayer 140B is less than that of the low doped layer 131. Accordingly, the recess-induced second sublayer 140B is served as a conditional transition structure between the low doped layer 131 and the active region 150 to maintain the epitaxial quality of the semiconductor stack.

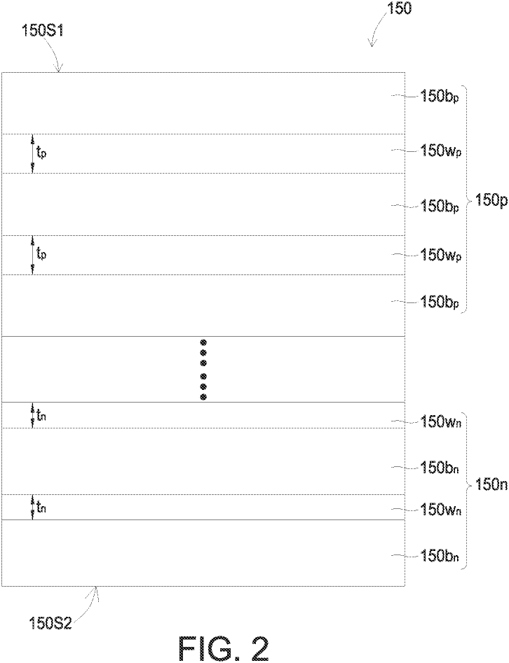

FIG. 2 shows an enlargement of a schematic cross-section of the active region 150 of semiconductor stack 1E in an embodiment of the present application. The active region 150 includes a multiple quantum well structure alternately stacked by a plurality of barrier layers 150b and well layers 150w. In one embodiment, the active region 150 includes N pairs of the alternately-stacked barrier layers 150b and well layers 150w from the lower surface 150S2 to the upper surface 150S1. When N is even, the bottom VB of the recess V may be disposed in or above the N/2 pair stacked sequentially from the lower surface 150S2. When N is odd, the bottom VB of the recess V may be disposed in or above (N+1)/2 pair stacked sequentially from the lower surface 150S2. In one embodiment, the multiple quantum well structure of the active region 150 includes a first region 150n and a second region 150p. The second region 150p is closer to the second-type semiconductor layer 160 than the first region 150n, and the first region 150n includes a quantum well structure alternately stacked by one or multiple barrier layers 150bₙ and well layers 150wₙ. The second region 150p includes a quantum well structure alternately stacked by one or more multiple barrier layers 150bₚ and one or more well layers 150wₚ, and the energy band gap of the barrier layer bₚ is larger than that of the well layer wₚ to restrict the carrier distribution. In addition, each of the plurality of well layers may have the same or different material composition and energy band gap. The present application does not limit thereto. In one embodiment, the thickness tₙ of the well layer 150wₙ in the first region 150n is different from the thickness tₚ of the well layer 150wₚ in the second region 150p. In one embodiment, the thickness tₙ of the well layer 150wₙ in the first region 150n is less than the thickness tₚ of the well layer 150wₚ in the second region 150p. By increasing the thickness 150wₚ of the well layer 150p in the second region 150p, the thickness tₚ of the well layer 150wₚ in the main recombination region for holes and electrons is increased to raise the recombination probability of holes and electrons, thereby improving the brightness. In addition, since the well layer 150wₙ not for main light-emitting has the thinner thickness tₙ, which may reduce the light emitted by the active region 150 from being absorbed by the material layers of itself, thereby effectively improving the light-emitting efficiency. In one embodiment, the energy band gap of the recess-induced layer 140 is greater than the energy band gap of the plurality of well layers 150wₙ and 150wₚ, and is less than or equal to the energy band gap of the barrier layer 150bₙ and 150bₚ. In one embodiment, the material of the barrier layer 150bₙ and 150bₚ includes Al_{d}Ga_{(1-d)}N, wherein 0 <d≦1, and the material of the recess-induced layer 140 includes Al_{c}Ga_{(1-c)}N, wherein 0<c≦1 and c<d≦1. In one embodiment, the material of 150wₙ and 150wₚ includes InₑAl_{f}Ga_{1-e-f}N, wherein 0<e≤1, 0≤f≤1. In one embodiment, e<0.02. In one embodiment, f<c<d.

Referring to FIG. 1, in one embodiment, semiconductor stack 1E may further include other layers between the first-type semiconductor layer 130 and the active region 150. For example, in order to reduce lattice mismatch between the first-type semiconductor layer 130 and the active region 150 that can cause the epitaxial defect, a stress-releasing structure (not shown) may be further formed between the first-type semiconductor layer 130 and the active region 150. The stress releasing layer can be a superlattice structure alternately stacked by two semiconductor layers composed of different materials. The two semiconductor layers are, for example, indium gallium nitride (InGaN) layer and gallium nitride (GaN) layer, or aluminum gallium nitride layer (AlGaN) layer and gallium nitride (GaN) layer. The stress-releasing structure can also be formed by a semiconductor stack including multiple layers having the same effect and different composed materials, such as a graduated multilayer structure composed by group III elements.

In one embodiment, the semiconductor stack 1E may further include an electron blocking region (not shown) between the active region 150 and the second-type semiconductor layer 160. The electron blocking region can block the electrons injected from the first-type semiconductor layer 130 into the active region 150 from entering the second-type semiconductor layer 160 without having been recombined with holes in the well layers of the active region 150. The electron blocking region has a higher energy band gap than that of the barrier layers in the active region 150. The electron blocking region may include a single layer, a plurality of sublayers, or a plurality of alternating first sublayers and second sublayers. In one embodiment, a plurality of alternating first sublayers and second sublayers form a superlattice structure. In one embodiment, the electron blocking region includes the second conductivity-type dopant, and the dopant concentration is greater than 1×10¹⁷ /cm³ and/or not greater than 1×10²¹/cm³.

In one embodiment, the second-type semiconductor layer 160 includes Al_{g}Ga_{(1-g)}N, wherein 0 < g ≦ 1. In one embodiment, the dopant concentration of the second conductivity-type dopant in the second-type semiconductor layer 160 is greater than 5×10¹⁸/cm³, for example, greater than 1×10¹⁹/cm³. In one embodiment, the second-type semiconductor layer 160 includes the first conductivity-type dopant, such as Si, which may form an ohmic contact with the electrode of the light-emitting element. In one embodiment, the dopant concentration of the second conductivity-type dopant is greater than that of the first conductivity-type dopant. In one embodiment, the dopant concentration of the second conductivity-type dopant is less than that of the first conductivity-type dopant. In some embodiments, the second-type semiconductor layer 160 includes a multilayer structure, such as a superlattice structure. By adjusting the dopant concentration or the gradience of composed materials of the multilayer structure, the epitaxial quality of the second-type semiconductor layer 160 can be improved. In one embodiment, the active region 150 and the second-type semiconductor layer 160 may include one or more layers other than the electron blocking region. For example, a diffusion prevention layer (not shown) may be disposed between the electronic barrier region and the active region 150. The diffusion prevention layer is used to prevent the second conductivity-type dopant of second-type semiconductor layer 160 or of the electron blocking region from diffusing into the active region 150. The deterioration of epitaxial quality or efficiency in the active region 150 can be avoided accordingly.

In one embodiment, the material of the recess-filled layer 161 includes AlₕGa₍₁₋ₕ₎N, wherein 0 < h ≦ 1 and the second-type semiconductor layer 160 includes Al_{g}Ga_{(1-g)}N, wherein 0 < g ≦ 1 and h < g ≦ 1. In one embodiment, the material of the recess-filled first sublayer 161A of the recess-filled layer 161 includes AlᵥGa₍₁₋ᵥ₎N, wherein0 < v ≦ 1. In one embodiment following the above embodiment, v < g ≦ 1. In one embodiment, the material of the recess-filled second sublayer 161B of the recess-filled layer 161 includes Al_{w}Ga_{(1-w)}N, wherein 0 < w ≦ 1. In one embodiment following the above embodiment, g < w ≦ 1. The concentration of the second conductivity-type dopant of the recess-filled layer 161 is less than that of the second-type semiconductor layer 160. In one embodiment, the concentration of the second conductivity-type dopant of the recess-filled layer 161 is greater than 1×10¹⁸/cm³, for example, greater than 3×10¹⁸/cm³, for example, between 3×10¹⁸/cm³ and 1×10¹⁹/cm³ (two endpoints included). In one embodiment, the concentrations of the second conductivity-type dopant of the recess-filled first sublayer 161A and the recess-filled second sublayer 161B are greater than 1×10¹⁸/cm³, for example, greater than 3×10¹⁸/cm³, for example, between 3×10¹⁸/cm³ and 1×10¹⁹/cm³ (two endpoints included). In one embodiment, the concentration of the second conductivity-type dopant of the recess-filled second sublayer 161B is greater than that of the recess-filled first sublayer 161A. In one embodiment, the thickness of the recess-filled first sublayer 161A is greater than or equal to that of the recess-filled second sublayer 161B. In one embodiment, the thickness of the recess-filled first sublayer 161A is between 50 nm and 200 nm (two endpoints included). In one embodiment, the thickness of the recess-filled second sublayer 161B is between 10 nm and 50 nm (two endpoints included).

By forming the recess-induced layer 140 between the first-type semiconductor layer 130 and/or low doped layer 131 and the active region 150, one or more recesses V can be formed in the active region 150. In a cross section of one recess V, a continuous inclined plane may be through the recess V, and the thicknesses of the barrier layers and well layers located on the inclined plane may be thinner than those on the planes outside of the recess V. For example, when the growth substrate is a sapphire substrate, since the surface for epitaxial growing the growth substrate is a polar plane (C-plane), and the inclined plane of the recess V is a semi-polar surface, holes may be easier to tunnel the barrier layers and the well layers. Accordingly the injection of holes can be increased to improve the light-emitting efficiency. In addition, the recess V may increase current spreading path, thereby improving anti-ESD effect of the semiconductor stack 1E. In addition, the appropriate number and size of recess V can reduce the probability of carriers falling into dislocation defects and reduce the conductivity and activity of dislocation defects, thereby reducing the probability of non-radiative recombination. Therefore, forward and reverse leakage of the light-emitting element may be effectively reduced. Further, the deterioration of light-emitting efficiency of the light-emitting element driven at high temperature or high current can be prevented, thereby improving the reliability of the light-emitting element. Further, since a main region for recombining holes and electrons in the well layer is closer to the second-type semiconductor layer 160, the light-emitting efficiency can be effectively improved by locating the recess in a part closer to the second-type semiconductor layer 160 of the active region 150. In addition, when growing the recess-filled first sublayer 161A of the recess-filled layer 161, the growth thereof is transformed from a three-dimensional growth into a two-dimensional growth to fill the recess V, so that the recess V has a filled surface VP in the recess-filled layer 161. In one embodiment, the filled surface VP may provide a flat surface to cooperate with the reflective structure in the light-emitting device of the following embodiments to improve the light-reflecting efficiency of the reflective structure. In one embodiment, the recess-filled second sub-layer 161B may be formed before forming the recess-filled first sub-layer 161A of the recess-filled layer 161. The concentration of the second conductivity-type dopant, such as Mg concentration of the recess-filled second sub-layer 161B, is greater than that of the recess-filled first sub-layer 161A, thereby increasing holes injected into the well layers of the active region 150 through the inner inclined plane of the recess V. In addition, since the concentration of the second conductivity-type dopant of the recess-filled first sub-layer 161A is less than that of the recess-filled second sublayer 161B, the light-absorption of recess-filled first sub-layer 161A caused by the excessive second conductivity-type dopants therein may be avoided. In one embodiment, the epitaxial structure of the recess-filled first sub-layer 161A is a continuous layered structure, and the epitaxial structure of the recess-filled second sub-layer 161B is stacked by a plurality of island structures. In one embodiment, the epitaxial surface reflectivity of the recess-filled first sub-layer 161A is greater than that of the recess-filled second sub-layer 161B.

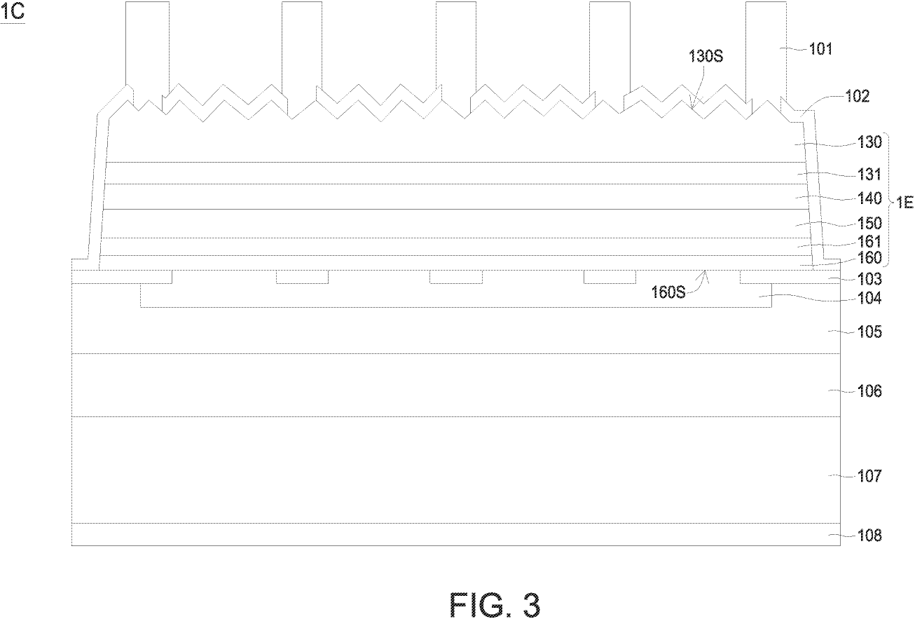

FIG. 3 shows a schematic cross-sectional view of a light-emitting element 1C in accordance with an embodiment of the present application. The light-emitting device 1C may include a support substrate 107, a second electrode structure 108 and the above-mentioned semiconductor stack 1E. The second electrode structure 108 and the semiconductor stack 1E are respectively disposed on opposite sides of the supporting substrate 107. In one embodiment, the semiconductor stack 1E originally grown on a growth substrate can be transferred and bonded to the support substrate 107, and then the growth substrate can be removed to expose the first-type semiconductor layer 130. The first-type semiconductor layer 130 has a first surface 130S, such as a light-emitting surface of the light-emitting element 1C. The second-type semiconductor layer 160 has a second surface 160S, such as a surface on a side opposite to the light-emitting surface of the light-emitting element 1C. In one embodiment, the first surface 130S of the first-type semiconductor layer 130 may include a roughing surface to improve the light-extraction efficiency.

The light-emitting device 1C may further include a first electrode structure 101, a patterned insulating layer 103, a metal reflective layer 104 and a metal barrier layer 105. The first electrode structure 101 may be disposed on the first surface 130S of the first-type semiconductor layer 130 to be in contact with the first-type semiconductor layer 130. The patterned insulating layer 103 and the metal reflective layer 104 can be disposed on the second surface 160S of the second-type semiconductor layer 160. The patterned insulating layer 103 can be disposed corresponding to a position of the first electrode structure 101. The width of the first electrode structure 101 may be smaller than that of the patterned insulating layer 103. The metal barrier layer 105 can be disposed on the patterned insulating layer 103 and the metal reflective layer 104. The metal barrier layer 105 and the semiconductor stack 1E are respectively disposed on opposite sides of the patterned insulating layer 103.

The light-emitting device 1C may further include a bonding layer 106 and a passivation layer 102. The bonding layer 106 is disposed between the metal barrier layer 105 and the supporting substrate 107. The passivation layer 102 may be disposed on the first surface 130S of the first-type semiconductor layer 130. The passivation layer 102 may cover a part of the first surface 130S of the first-type semiconductor layer 130, and is extended to cover the side surfaces of the semiconductor stack 1E. The passivation layer 102 can further cover the patterned insulating layer 103. The first electrode structure 101 may penetrate the passivation layer 102 and contact the first-type semiconductor layer 130. In one embodiment, the first electrode structure 101 is located on the passivation layer 102 and covers a part of the passivation layer 102. In one embodiment, the passivation layer 102 is not covered by the first electrode structure 12. In one embodiment, the passivation layer 102 may cover the side surfaces and a part of the upper surface of the first electrode structure 12. In one embodiment, the passivation layer 102 may conformally cover a rough surface of the first-type semiconductor layer 130, therefore the passivation layer 102 may have an upper surface including a concave-convex pattern. The metal barrier layer 105 may be able to prevent the materials of the bonding layer 106 from diffusing into the metal reflective layer 104 during the manufacturing process. The diffused materials of the bonding layer 106 may be reacted with the metal reflective layer 104 to form a compound or alloy affecting the reflectivity and conductivity of the metal reflective layer 104. The bonding layer 106 may connect the support substrate 107 and the semiconductor stack 1E.

In one embodiment, the supporting substrate 107 includes conductive materials or semiconductor materials, and the supporting substrate 107 may be transparent or opaque. The support substrate 107 may include a conductive material but is not limited to transparent conductive oxide (TCO), such as zinc oxide (ZnO), indium tin oxide (ITO), indium zinc oxide (IZO), gallium oxide (Ga₂O₃), lithium gallate (LiGaO₂), lithium aluminate (LiAlO₂) or magnesium aluminate (MgAl₂O₄), or may include conductive materials but not limited to metal materials such as aluminum (Al), copper (Cu), molybdenum (Mo), germanium (Ge) or tungsten (W) or alloys or stacks of the above materials; or may include but not limited to semiconductor materials, such as silicon (Si), silicon carbide (SiC), gallium arsenide (GaAs), gallium nitride (GaN), Aluminum Nitride (AlN), Gallium Phosphide (GaP), Gallium Arsenide Phosphorus (GaAsP), Zinc Selenide (ZnSe), Zinc Selenide (ZnSe), or Indium Phosphide (InP).

The first electrode structure 101 may include a conductive material. The first electrode structure 101 and the second electrode structure 108 may include the same or different materials. The first electrode structure 101 and the second electrode structure 108 may include metal materials or transparent conductive materials; for example, the metal materials may include but not limited to aluminum (Al), chromium (Cr), copper (Cu), tin (Sn), gold (Au), Nickel (Ni), Titanium (Ti), Platinum (Pt), Palladium (Pd), Silver (Ag), Lead (Pb), Zinc (Zn), Cadmium (Cd), Antimony (Sb), Cobalt (Co) or alloys of the above materials; transparent conductive materials may include but not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), aluminum gallium arsenide (AlGaAs), gallium nitride (GaN), Gallium phosphide (GaP), gallium arsenide (GaAs), gallium arsenide phosphide (GaAsP), indium zinc oxide (IZO), diamondlike carbon (DLC) or graphene. In one embodiment, the first electrode structure 101 and the second electrode structure 108 respectively include single-layer or multi-layer structures.

The material of the patterned insulating layer 103 may include an insulating oxide, nitride, silicon oxide, titanium oxide, aluminum oxide, magnesium fluoride or silicon nitride. The material of the passivation layer 102 may include silicon nitride or silicon oxide. The material of the patterned insulating layer 103 may be different from that of the passivation layer 102. In one embodiment, the material of the patterned insulating layer 103 can be titanium dioxide (TiO₂), and the material of the protective layer 102 can be silicon dioxide (SiO₂) or silicon nitride (SiNₓ or Si₃N₄). Because titanium dioxide has a better anti-etching characteristic, the patterned insulating layer 103 made of titanium dioxide can serve as an etching stop layer when etching the semiconductor stack 1E in the subsequent dicing process. Because silicon dioxide or silicon nitride have a better light-penetration characteristic, the passivation layer 102 made of silicon dioxide or silicon nitride is less likely to absorb light.

The metal reflective layer 104 may include metal material such as silver (Ag), gold (Au), aluminum (Al), titanium (Ti), chromium (Cr), copper (Cu), nickel (Ni), platinum (Pt), ruthenium (Ru), tungsten (W), rhodium (Rh) or an alloy or a stack of the above materials. In one embodiment, the metal reflective layer 104 may include a multi-layer structure (not shown), for example, the metal reflective layer 104 may include a multi-layer structure stacked by a first metal layer, a second metal layer and a third metal layer. The first metal layer, the second metal layer and the third metal layer are stacked in sequence. The first metal layer may include silver (Ag), the second metal layer may include titanium tungsten (TiW), and the third metal layer may include platinum (Pt). The metal reflective layer 104 may form an ohmic contact with the second-type semiconductor layer 160.

The metal barrier layer 105 may include metal materials such as aluminum (Al), chromium (Cr), platinum (Pt), titanium (Ti), tungsten (W), zinc (Zn), or an alloy or a stack including above materials. In one embodiment, when the metal barrier layer 105 is a metal stack, the metal barrier layer 105 is alternately stacked by two or more metal layers, such as Cr/Pt, Cr/Ti, Cr/TiW, Cr/W, Cr/Zn, Ti/Pt, Ti/W, Ti/TiW, Ti/Zn, Pt/TiW, Pt/W, Pt/Zn, TiW/W, TiW/Zn, or W/Zn.

The bonding layer 106 may include transparent conductive material or metal material. The transparent conductive material includes but are not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), Indium titanium oxide (ITiO), indium zinc oxide (IZO), indium gallium oxide (IGO), gallium aluminum zinc oxide (GAZO), graphene or a combination of the above materials. The metal material includes but are not limited to copper (Cu), aluminum (Al), tin (Sn), gold (Au), silver (Ag), lead (Pb), titanium (Ti), nickel (Ni), platinum (Pt), tungsten (W) or an alloy or a stack including above materials.

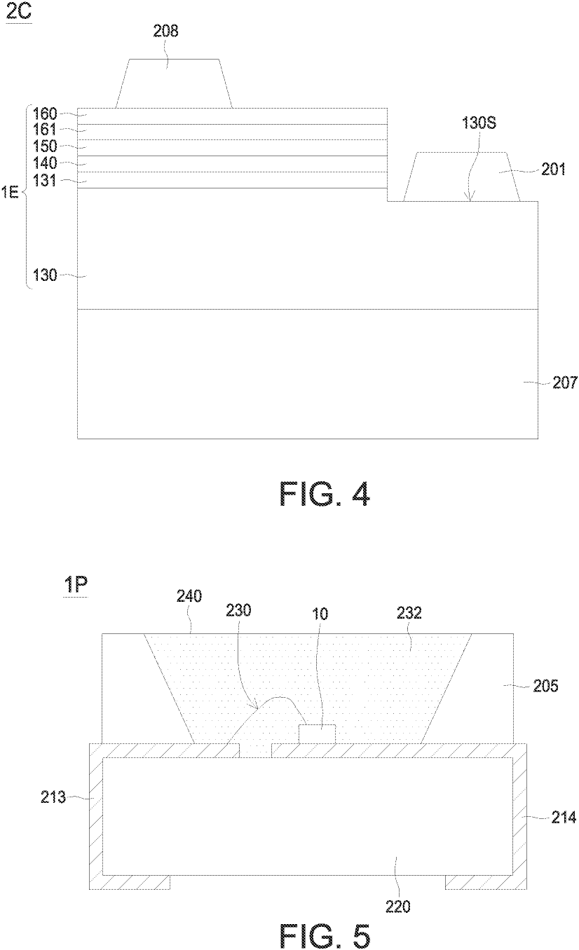

FIG. 4 shows a schematic cross-sectional view of a light-emitting element 2C in accordance with an embodiment of the present application. The light-emitting device 2C includes a carrier 207 and the above-mentioned semiconductor stack 1E on the carrier 207. The first-type semiconductor layer 130 has a first surface 130S not covered by the active region 150 and the second-type semiconductor layer 160. A first electrode structure 201 is located on and electrically connected to the first surface 130S of the first-type semiconductor layer 130, and the second electrode structure 208 is located on and electrically connected to the second-type semiconductor layer 160. In one embodiment, a transparent conductive layer (not shown) may be disposed between the second electrode structure 208 and the second-type semiconductor layer 160. For a current blocking purpose, a patterned insulating layer may be disposed between the transparent conductive layer and the second-type semiconductor layer 160, and/or another patterned insulating layer may be disposed between the first electrode structure 201 and the first-type semiconductor layer 130. In one embodiment, the carrier 207 may be a growth substrate for growing the above-mentioned semiconductor stack 1E. In one embodiment, the carrier 207 may be a patterned substrate, that is, the carrier 207 has a patterned structure (not shown) on a surface where the semiconductor stack 1E is located. The light emitted from the semiconductor stack 1E may be refracted and/or reflected by the patterned structure of the carrier 207, thereby improving the brightness of the light-emitting element. In one embodiment, if the light-emitting element 2C is packaged in a flip-chip form, a reflective structure may be provided between the second electrode structure 208 and the second-type semiconductor layer 160, and the reflective structure may include a metal reflective structure or an insulating reflective structure. In one embodiment, the metal reflective structure may include a single metal layer or a stack formed by multiple metal layers. In one embodiment, the material of the metal reflective structure includes a metal material with high reflectivity to the light emitted by the active region 150, such as silver (Ag), gold (Au), aluminum (Al), titanium (Ti), chromium (Cr), copper (Cu), nickel (Ni), platinum (Pt), ruthenium (Ru), tungsten (W), zinc (Zn), rhodium (Rh), or an alloy or a stack of above materials. In one embodiment, the insulating reflective structure may include a reflective structure composed of a material stack. The material stack is stacked according to different refractive index materials selection and thickness design. For example, the material stack is a distributed Bragg reflector (DBR) to provide reflectivity for light in a specific wavelength range emitted by the active region 150. In one embodiment, the material stack is formed by dielectric materials, and the dielectric materials include silicon-containing material, such as silicon oxide (SiOₓ), silicon nitride (SiNₓ), or silicon oxynitride (SiOₓN_{y}); metal oxide, such as niobium oxide (Nb₂O₅), tantalum oxide (Ta₂O₅), hafnium oxide (HfO₂), titanium oxide (TiOₓ), or aluminum oxide (Al₂O₃); metal fluorides, such as magnesium fluoride (MgF₂).

The first electrode structure 201 and the second electrode structure 208 are for electrically connecting to an external power source or other electronic components and for conducting a current therebetween. Materials of the first electrode structure 201 and the second electrode structure 208 include metal materials. Metal materials include chromium (Cr), gold (Au), aluminum (Al), copper (Cu), silver (Ag), tin (Sn), nickel (Ni), rhodium (Rh), platinum (Pt), germanium gold nickel (GeAuNi), titanium (Ti), beryllium gold (BeAu), germanium gold (GeAu) or zinc gold (ZnAu). In some embodiments, each of the first electrode structure 201 and the second electrode structure 208 is a single layer, or a structure including multiple layers such as Ti/Au layer, Ti/Al layer, Ti/Pt/Au layer, Cr/Au layer, Cr/Pt/Au layer, Ni/Au layer, Ni/Pt/Au layer, Ti/Al/Ti/Au layer, Cr/Ti/Al/Au layer, Cr/Al/Ti/Au layer, Cr/Al/Ti/Pt layer or Cr/Al/Cr/Ni/Au layer, or a combination thereof. The material of the transparent conductive layer includes transparent conductive oxide or light-transmissive thin metal. The transparent conductive oxides are, for example, indium tin oxide (ITO), indium oxide (InO), tin oxide (SnO), cadmium tin oxide (CTO), antimony tin oxide (ATO), aluminum zinc oxide (AZO), zinc tin oxide (Zn₂SnO₄, ZTO), gallium doped zinc oxide (GZO), tungsten doped indium oxide (IWO), zinc oxide (ZnO) or indium zinc oxide (IZO). Among them, thin metals that can transmit light are chromium (Cr), gold (Au), aluminum (Al), copper (Cu), silver (Ag), tin (Sn), nickel (Ni), rhodium (Rh), platinum (Pt) or titanium (Ti).

FIG. 5 shows a schematic cross-sectional view of a light-emitting package 1P in accordance with an embodiment of the present application. The light-emitting package 1P in accordance with the embodiment may include an encapsulation wall 205, an encapsulation substrate 201, external electrodes 213 and 214 installed on the encapsulation substrate 201, and a light-emitting element 10 installed in the encapsulation wall 205 and electrically connected to the external electrodes 213 and 214. And the packaging material 240 (which includes phosphor 232 to surround the light-emitting element 10). The external electrodes 213 and 214 are electrically insulated from each other, and provide power to the light-emitting element 10 by the wire 230. In addition, the external electrodes 213 and 214 may reflect light emitted from the light-emitting element 10 to improve light extraction efficiency and dissipate heat of the light-emitting element 10 to outside. The light-emitting element 10 may be the light-emitting element 1C in the foregoing embodiments. The light-emitting package 1P may be applied to a backlight unit, a lighting unit, a display device, an indicator, a lamp, a street lamp, a lighting device for a vehicle, a display device for a vehicle, or a smart watch, but is not limited thereto.

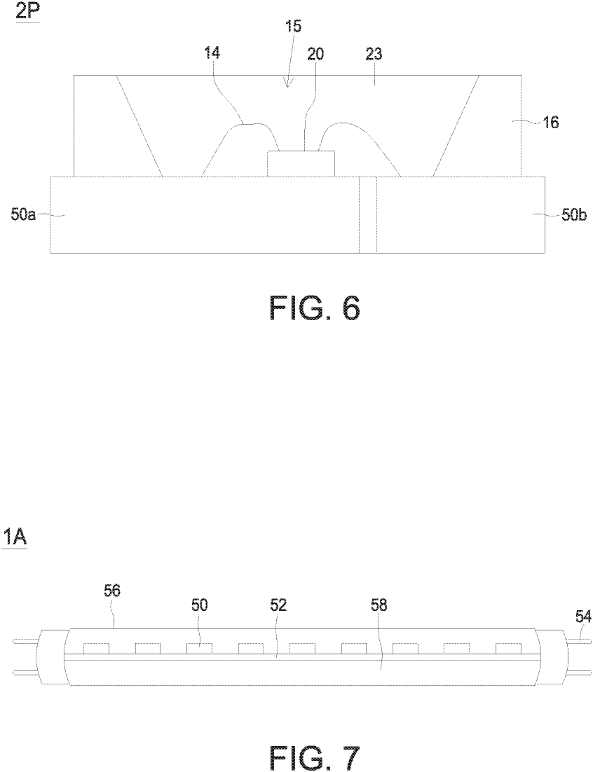

FIG. 6 shows a schematic cross-sectional view of a light-emitting package 2P in accordance with an embodiment of the present application. As shown in FIG. 6, the light-emitting package 2P includes a body 16 having a chamber 15, a first terminal 50a and second terminal 50b disposed in the body 16, light-emitting elements 20, wires 14 and a packaging material 23. The chamber 15 may include an opening structure recessed from the top surface of the body 16. In one embodiment, the sidewall of the chamber 15 may include a reflective structure. The first terminal 50a is arranged in a first region of a bottom area of the chamber 15, the second terminal 50b is arranged in a second area of the bottom area of the chamber 15. In the chamber, the first terminal 50a and the second terminal 50b are spaced apart from each other. The light-emitting element 20 is disposed on at least one of the first and second terminals 50a and 50b. For example, the light-emitting element 20 can be disposed on the first terminal 50a, and the first electrode structure 201 (shown in FIG. 4) and the second electrode structure 208 (shown in FIG. 4) of the light-emitting element are electrically connected to the first and second wires terminals 50a and 50b by wires 14, respectively. The packaging material 23 is disposed in the chamber 15 of the body 16 and covers the light-emitting element 20. The packaging material 23 includes, for example, silicon or epoxy resin, and the structure thereof can be single-layer or multi-layer. In one embodiment, the packaging material 23 may further include a wavelength conversion material, such as phosphor and/or a scattering material, for converting the wavelength of the light generated by the light-emitting element 20. The light-emitting element 20 may be the light-emitting element 2C in the foregoing embodiments. The light-emitting package 2P may be applied to a backlight unit, a lighting unit, a display device, an indicator, a lamp, a street lamp, a lighting device for a vehicle, a display device for a vehicle, or a smart watch, but is not limited thereto.

FIG. 7 shows a schematic cross-sectional view of a light-emitting device 1A in accordance with an embodiment of the present application. The light-emitting device 1A includes a light-emitting element 50 mounted on a circuit board 52 in a shape of long-flat plate. A plurality of light-emitting elements 50 are disposed on one side of the circuit board 52, and arranged at intervals from each other along the longitudinal direction of the circuit board 52. On the other side of the circuit board 52, a heatsink 58 is provided to dissipate the heat generated by the light-emitting element 50. On the side where the light-emitting element 50 is mounted, a transparent cover 56 made of a material that can be easily passed through by emitted-light of the light-emitting element 50 is provided. In addition, for providing electric power to the circuit board 52, terminals 54 are provided at both ends of the light-emitting device 1A to connect to a power source (not shown). The light-emitting element 50 may be the light-emitting element 1C, 2C of the foregoing embodiments.

It is noted that each of the embodiments listed in the present application is merely used to describe the present application, not limiting the scope of the present application. It will be apparent to any one that obvious modifications or variations can be made to the devices in accordance with the present disclosure without departing from the spirit and scope of the present application. Identical or similar components in different embodiments or the components having identical reference numerals in different embodiments have identical physical properties or chemical properties. In addition, under suitable circumstances, the above-mentioned embodiments in the present application may be combined or replaced with each other, not limiting to the specific embodiments described above. In one embodiment, the connecting relationship of the specific component and other component described in detail may also be applied into other embodiments, falling within the scope of the following claims and their equivalents of the present application.

What is claimed is:

1. A semiconductor stack, comprising:
a first-type semiconductor layer;
a second-type semiconductor layer;
an active region located between the first-type semiconductor layer and the second-type semiconductor layer and having a first thickness, wherein the active region comprises an upper surface and a lower surface closer to the first-type semiconductor layer than the upper surface;
one or multiple recesses respectively comprises a bottom, wherein the bottom is disposed in the active region; and
a recess-induced layer located between the first-type semiconductor layer and the active region;
wherein a first distance from the bottom to the lower surface is 0.5-0.9 times the first thickness.

2. The semiconductor stack according to claim 1, wherein each of the active region, the recess-induced layer and the first-type semiconductor layer comprises a group IV dopant, wherein the group IV dopant of the active region comprises a first group IV dopant concentration, the group IV dopant of the recess-induced layer comprises a second group IV dopant concentration, and the group IV dopant of the first-type semiconductor layer comprises a third group IV dopant concentration.

3. The semiconductor stack according to claim 2, wherein the second group IV dopant concentration is greater than or equal to the third group IV dopant concentration, or the first group IV dopant concentration is greater than or equal to the second group IV dopant concentration.

4. The semiconductor stack according to claim 2, wherein the recess-induced layer directly contacts the lower surface.

5. The semiconductor stack according to claim 4, wherein the recess-induced layer comprises a recess-induced first sublayer and a recess-induced second sublayer, the recess-induced first sublayer is between the recess-induced second sublayer and the active region.

6. The semiconductor stack according to claim 5, wherein the recess-induced first sublayer comprises the second group IV dopant concentration, the recess-induced second sublayer comprises a fourth group IV dopant concentration different from the second group IV dopant concentration.

7. The semiconductor stack according to claim 5, wherein a thickness of the recess-induced first sublayer is greater than that of the recess-induced second sublayer.

8. The semiconductor stack according to claim 1, wherein each of the one or multiple recesses comprises a V-shaped recess.

9. The semiconductor stack according to claim 1, wherein the recess-induced layer comprises a second thickness, wherein the first distance is 0.3-2.7 times the first thickness.

10. The semiconductor stack according to claim 9, wherein a sum of the second thickness and the first distance is 0.6-1 times a sum of the second thickness and the first thickness.

11. The semiconductor stack according to claim 9, wherein the first thickness is 0.4-0.8 times the sum of the second thickness and the first thickness.

12. The semiconductor stack according to claim 1, wherein each of the one or multiple recesses comprises a maximum opening width from 50 nm to 200 nm.

13. The semiconductor stack according to claim 1, further comprising a recess-filled layer between the second-type semiconductor layer and the active region, wherein the one or the multiple recesses respectively comprises a filled surface in the recess-filled layer and comprises a depth, wherein a second distance between the filled surface and the upper surface is 0.1-3 times the depth.

14. The semiconductor stack according to claim 13, wherein the depth is in a range of 50-250 nm.

15. The semiconductor stack according to claim 13, wherein the second distance is in a range of 25-150 nm.

16. The semiconductor stack according to claim 13, wherein the recess-filled layer comprises a recess-filled first sub-layer and a recess-filled second sub-layer, and the recess-filled second sub-layer is between the recess-filled first sub-layer and the active region.

17. The semiconductor stack according to claim 16, wherein each of the recess-filled first sub-layer and the recess-filled second sub-layer comprises a second conductivity-type dopant, wherein the second conductivity-type dopant of the recess-filled first sub-layer comprises a first second conductivity-type dopant concentration, the second conductivity-type dopant of the recess-filled second sub-layer comprises a second second conductivity-type dopant concentration, and the first second conductivity-type dopant concentration is less than the second second conductivity-type dopant concentration.

18. The semiconductor stack according to claim 2, further comprising a low doped layer between the first-type semiconductor layer and the recess-induced layer, wherein each of the low doped layer, the first-type semiconductor layer and the recess-induced layer comprises a first conductivity-type dopant, wherein the first conductivity-type dopant of the low doped layer comprises a first first conductivity-type dopant concentration, the first conductivity-type dopant of the first-type semiconductor layer comprises a second first conductivity-type dopant concentration, the first conductivity-type dopant of the recess-induced layer comprises a third first conductivity-type dopant concentration, wherein the group IV dopant comprises carbon, and the first conductivity-type dopant is different from the group IV dopant.

19. The semiconductor stack according to claim 18, wherein the third first conductivity-type dopant concentration is less than the second first conductivity-type dopant concentration, or the third first conductivity-type dopant concentration is greater than or equal to the first first conductivity-type dopant concentration.

20. The semiconductor stack according to claim 1, wherein the active region comprises N pairs of alternately stacked barrier layers and well layers, wherein:
when N is even, the bottom of the recess is disposed in or above the N/2 pair stacked sequentially from the lower surface; and
when N is odd, the bottom of the recess is disposed in or above (N+1)/2 pair stacked sequentially from the lower surface.
